(19) United States
(12) Patent Application Publication
(10) Pub. No.: US 2025/0323147 A1
(43) Pub. Date: Oct. 16, 2025

(54) OUTPUT DRIVER WITH COMPACT INDUCTIVE OUTPUT DRIVER WITH COMPACT INDUCTIVE PEAKING

(71) Applicant: Micron Technology, Inc., Boise, ID (US)

(72) Inventors: Chulkyu Lee, Meridian, ID (US); Timothy M. Hollis, Meridian, ID (US)

(21) Appl. No.: 19/046,372

(22) Filed: Feb. 5, 2025

Related U.S. Application Data
(60) Provisional application No. 63/634,781, filed on Apr. 16, 2024.

(51) Int. Cl. H01L 23/522; H01L 23/00; H01L 23/528

(52) U.S. Cl. CPC H01L 23/5227; H01L 23/528; H01L 24/02; H01L 24/08; H01L 2224/02375; H01L 2224/08175; H01L 2924/30101; H01L 2924/30105; H01L 2924/30107

(57) ABSTRACT

Methods, systems, and devices for an output driver with compact inductive peaking are described. A memory system may implement a circuit for communicating signaling with a host system. The circuit may include a transmission component for transmitting signaling, and a reception component for receiving signaling, where the transmission component and the reception component are coupled with a pad. The circuit may include a current stabilization component and a drain capacitor to store charge associated with the transmission component. The circuit may include a series inductor coupled with the transmission component, the reception component, the drain capacitor, the current stabilization component, and the pad. A capacitance of the pad may be based on a resistance and an inductance of the series inductor.

### CROSS REFERENCE

The present Application for Patent claims priority to U.S. Patent Application No. 63/634,781 by Lee et al., entitled “OUTPUT DRIVER WITH COMPACT INDUCTIVE PEAKING,” filed Apr. 16, 2024, which is assigned to the assignee hereof, and which is expressly incorporated by reference in its entirety herein.

### TECHNICAL FIELD

The following relates to one or more systems for memory, including an output driver with compact inductive peaking.

### BACKGROUND

Memory devices are used to store information in devices such as computers, user devices, wireless communication devices, cameras, digital displays, and others. Information is stored by programming memory cells within a memory device to various states. For example, binary memory cells may be programmed to one of two supported states, often denoted by a logic 1 or a logic 0. In some examples, a single memory cell may support more than two states, any one of which may be stored by the memory cell. To store information, a memory device may write (e.g., program, set, assign) states to the memory cells. To access stored information, a memory device may read (e.g., sense, detect, retrieve, determine) states from the memory cells.

### BRIEF DESCRIPTION OF THE DRAWINGS

FIG. 1 shows an example of a system that supports an output driver with compact inductive peaking in accordance with examples as disclosed herein.

FIG. 2 shows an example of a circuit that supports an output driver with compact inductive peaking in accordance with examples as disclosed herein.

FIG. 3 shows an example of a circuit that supports an output driver with compact inductive peaking in accordance with examples as disclosed herein.

FIGS. 4A and 4B show examples of memory architectures that support an output driver with compact inductive peaking in accordance with examples as disclosed herein.

FIG. 5 shows a block diagram of a circuit that supports an output driver with compact inductive peaking in accordance with examples as disclosed herein.

FIG. 6 shows a flowchart illustrating a method or methods that support an output driver with compact inductive peaking in accordance with examples as disclosed herein.

### DETAILED DESCRIPTION

Some systems may implement a circuit configured to communicate data between a respective memory system and host system. For example, the circuit (e.g., an input/output (I/O) circuit) may be implemented within a memory system (e.g., at a memory device, at a memory system controller), and may be configured to transmit data to and receive data from the host system coupled with the memory system. The I/O circuit may include a quantity of components (e.g., transistors, capacitors, and resistors), such as output drivers and receivers for communicating the data, and supporting components (e.g., charge drains, current stabilization components) configured to support various functions of the output drivers and receivers. For example, the supporting components may include capacitors and resistors configured to store excess charge or prevent current spiking of the I/O circuit, among other functions. Additionally, the I/O circuit may include a pad configured to receive and transmit data (e.g., from and to a host system). In some instances, however, the pad may have an undesirable parasitic capacitance, which may be caused by capacitors leaking charge onto a data line coupled with the pad. In some such cases, the parasitic capacitance of the pad may result in the overall bandwidth of the memory system being undesirably reduced. Accordingly, a circuit having a pad with a relatively low parasitic capacitance may be desirable.

A circuit having a pad with a relatively low parasitic capacitance is described herein. In accordance with examples as described herein, an I/O circuit may implement a series inductor configured to reduce parasitic capacitance of one or more components. The I/O circuit may include one or more output drivers configured to drive signaling to a pad configured to output data associated with the signaling. Additionally, or alternatively, the I/O circuit may include one or more receivers configured to receive signaling from the pad. Further, the I/O circuit may include a drain capacitor configured to store charge associated with the one or more output drivers, and a current stabilization component configured to prevent current spikes (on lines or components associated with the circuit). The series inductor may be coupled with the driver and receiver and may include (e.g., have) a series inductance and a series resistance. Accordingly, the series inductor may reduce the parasitic capacitance of the pad, which may result in the pad being able to transmit and receive relatively large quantities of data with relatively low latency. That is, the presence of the series inductor may result in the overall bandwidth of the memory system being increased.

In addition to applicability in memory systems as described herein, techniques for an output driver with compact inductive peaking may be generally implemented to improve the performance of various electronic devices and systems (including artificial intelligence (AI) applications, augmented reality (AR) applications, virtual reality (VR) applications, and gaming). Some electronic device applications, including high-performance applications such as AI, AR, VR, and gaming, may be associated with relatively high processing requirements to satisfy user expectations. As such, increasing processing capabilities of the electronic devices by decreasing response times, improving power consumption, reducing complexity, increasing data throughput or access speeds, decreasing communication times, or increasing memory capacity or density, among other performance indicators, may improve user experience or appeal. Implementing the techniques described herein may improve the performance of electronic devices by reducing parasitic capacitance of an I/O circuit, which may support increased data throughput, among other benefits.

Features of the disclosure are illustrated and described in the context of systems and architectures. Features of the disclosure are further illustrated and described in the context of I/O circuits and flowcharts.

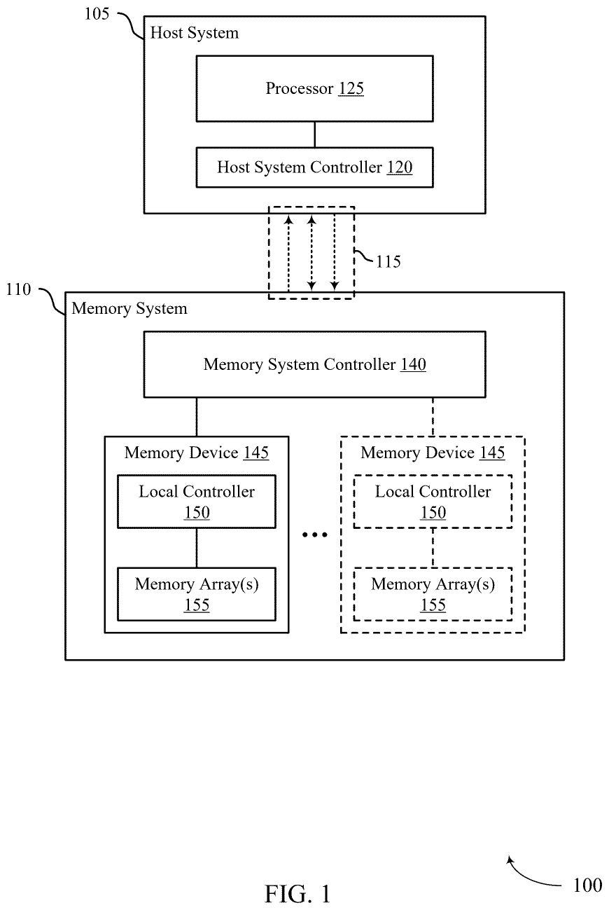

FIG. 1 illustrates an example of a system 100 that supports an output driver with compact inductive peaking in accordance with examples as disclosed herein. The system 100 may include portions of an electronic device, such as a computing device, a mobile computing device, a wireless communications device, a graphics processing device, a vehicle, a smartphone, a wearable device, an internet-connected device, a vehicle controller, a system on a chip (SoC), or other stationary or portable electronic system, among other examples. The system 100 includes a host system 105, a memory system 110, and one or more channels 115 coupling the host system 105 with the memory system 110 (e.g., to support a communicative coupling). The system 100 may include any quantity of one or more memory systems 110 coupled with the host system 105.

The host system 105 may include one or more components (e.g., circuitry, processing circuitry, one or more processing components) that use memory to execute processes, any one or more of which may be referred to as or be included in a processor 125. The processor 125 may include at least one of one or more processing elements that may be co-located or distributed, including a general-purpose processor, a digital signal processor (DSP), an application-specific integrated circuit (ASIC), a field-programmable gate array (FPGA) or other programmable logic device, a controller, discrete gate or transistor logic, one or more discrete hardware components, or a combination thereof. The processor 125 may be an example of a central processing unit (CPU), a graphics processing unit (GPU), a general-purpose GPU (GPGPU), or an SoC or a component thereof, among other examples.

The host system 105 may also include at least one of one or more components (e.g., circuitry, logic, instructions) that implement the functions of an external memory controller (e.g., a host system memory controller), which may be referred to as or be included in a host system controller 120. For example, a host system controller 120 may issue commands or other signaling for operating the memory system 110, such as write commands, read commands, configuration signaling or other operational signaling. In some examples, the host system controller 120, or associated functions described herein, may be implemented by or be part of the processor 125. For example, a host system controller 120 may be hardware, instructions (e.g., software, firmware), or some combination thereof implemented by the processor 125 or other component of the host system 105. In various examples, a host system 105 or a host system controller 120 may be referred to as a host.

The memory system 110 provides physical memory locations (e.g., addresses) that may be used or referenced by the system 100. The memory system 110 may include a memory system controller 140 and one or more memory devices 145 (e.g., memory packages, memory dies, memory chips) operable to store data. The memory system 110 may be configurable for operations with different types of host systems 105, and may respond to commands from the host system 105 (e.g., from a host system controller 120). For example, the memory system 110 (e.g., a memory system controller 140) may receive a write command indicating that the memory system 110 is to store data received from the host system 105, or receive a read command indicating that the memory system 110 is to provide data stored in a memory device 145 to the host system 105, or receive a refresh command indicating that the memory system 110 is to refresh data stored in a memory device 145, among other types of commands and operations.

A memory system controller 140 may include at least one of one or more components (e.g., circuitry, logic, instructions) operable to control operations of the memory system 110. A memory system controller 140 may include hardware or instructions that support the memory system 110 performing various operations, and may be operable to receive, transmit, or respond to commands, data, or control information related to operations of the memory system 110. A memory system controller 140 may be operable to communicate with one or more of a host system controller 120, one or more memory devices 145, or a processor 125. In some examples, a memory system controller 140 may control operations of the memory system 110 in cooperation with the host system controller 120, a local controller 150 of a memory device 145, or any combination thereof. Although the example of memory system controller 140 is illustrated as a separate component of the memory system 110, in some examples, aspects of the functionality of the memory system 110 may be implemented by a processor 125, a host system controller 120, at least one of one or more local controllers 150, or any combination thereof.

Each memory device 145 may include a local controller 150 and one or more memory arrays 155. A memory array 155 may be a collection of memory cells (e.g., a two-dimensional array, a three-dimensional array), with each memory cell being operable to store data (e.g., as one or more stored bits). Each memory array 155 may include memory cells of various architectures, such as random access memory (RAM) cells, dynamic RAM (DRAM) cells, synchronous dynamic RAM (SDRAM) cells, static RAM (SRAM) cells, ferroelectric RAM (FeRAM) cells, magnetic RAM (MRAM) cells, resistive RAM (RRAM) cells, phase change memory (PCM) cells, chalcogenide memory cells, not-or (NOR) memory cells, and not-and (NAND) memory cells, or any combination thereof.

A local controller 150 may include at least one of one or more components (e.g., circuitry, logic, instructions) operable to control operations of a memory device 145. In some examples, a local controller 150 may be operable to communicate (e.g., receive or transmit data or commands or both) with a memory system controller 140. In some examples, a memory system 110 may not include a memory system controller 140, and a local controller 150 or a host system controller 120 may perform functions of a memory system controller 140 described herein. In some examples, a local controller 150, or a memory system controller 140, or both may include decoding components operable for accessing addresses of a memory array 155, sense components for sensing states of memory cells of a memory array 155, write components for writing states to memory cells of a memory array 155, or various other components operable for supporting described operations of a memory system 110.

A host system 105 (e.g., a host system controller 120) and a memory system 110 (e.g., a memory system controller 140) may communicate information (e.g., data, commands, control information, configuration information, timing information) using one or more channels 115. Each channel 115 may be an example of a transmission medium that carries information, and each channel 115 may include one or more signal paths (e.g., a transmission medium, an electrical conductor, a conductive path) between terminals (e.g., nodes, pins, contacts) associated with the components of the system 100. A terminal may be an example of a conductive input or output point of a device of the system 100, and a terminal may be operable as part of a channel 115. To support communications over channels 115, a host system 105 (e.g., a host system controller 120) and a memory system 110 (e.g., a memory system controller 140) may include receivers (e.g., latches) for receiving signals, transmitters (e.g., drivers) for transmitting signals, decoders for decoding or demodulating received signals, or encoders for encoding or modulating signals to be transmitted, among other components that support signaling over channels 115, which may be included in a respective interface portion of the respective system.

A channel 115 may be dedicated to communicating one or more types of information, and channels 115 may include unidirectional channels, bidirectional channels, or both. For example, the channels 115 may include one or more command/address channels, one or more clock signal channels, one or more data channels, among other channels or combinations thereof. In some examples, a channel 115 may be configured to provide power from one system to another (e.g., from the host system 105 to the memory system 110, in accordance with a regulated voltage). In some examples, at least a subset of channels 115 may be configured in accordance with a protocol (e.g., a logical protocol, a communications protocol, an operational protocol, an industry standard), which may support configured operations of and interactions between a host system 105 and a memory system 110.

The memory system 110 may implement an I/O circuit configured to communicate data between the memory system 110 and the host system 105. For example, the I/O circuit may be implemented within memory system 110 at the memory device 145 or at the memory system controller 140, and may be configured to transmit data to and receive data from the host system 105. The I/O circuit may include a quantity of components (e.g., transistors, capacitors, and resistors), such as output drivers and receivers for communicating the data, and supporting components (e.g., charge drains, current stabilization components) configure to support functions of the output drivers and receivers.

In accordance with examples as described herein, an I/O circuit may implement a series inductor configured to reduce parasitic capacitance of one or more components. The I/O circuit may include one or more output drivers configured to drive signaling to a pad configured to output data associated with the signaling. Additionally, or alternatively, the I/O circuit may include one or more receivers configured to receive signaling from the pad. Further, the I/O circuit may include a drain capacitor configured to store charge associated with the one or more output drivers, and a current stabilization component configured to prevent current spikes (on lines or components associated with the circuit). The series inductor may be coupled with the driver and receiver and may include (e.g., have) a series inductance and a series resistance. Accordingly, the series inductor may reduce the parasitic capacitance of the pad, which may result in the pad being able to transmit and receive relatively large quantities of data with relatively low latency. That is, the presence of the series inductor may result in the overall bandwidth of the memory system 110 being increased.

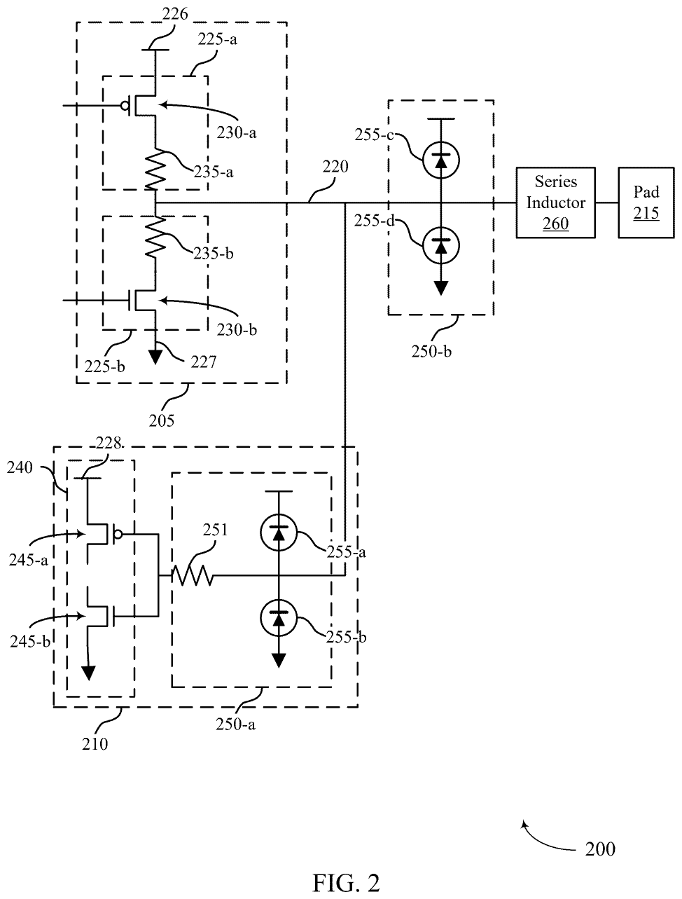

FIG. 2 shows an example of a circuit 200 that supports an output driver with compact inductive peaking in accordance with examples as disclosed herein. The circuit 200 may be implemented within a system, which may be an example of a system 100, as described with reference to FIG. 1. For example, the circuit 200 may be implemented within the memory system 110 and facilitate communications with the host system 105. In some examples, the circuit 200 may be implemented at a memory device 145 (e.g., within a local controller 150 of the memory device 145) or at a memory system controller 140. Although some elements of the circuit 200 may be illustrated according to an order along (e.g., within) the circuit, the elements of the circuit 200 may be implemented in various other orders not shown. That is, FIG. 2 is an example implementation of an I/O circuit. The circuit 200 may implement a series inductor 260 which may be configured to reduce a parasitic capacitance of the circuit 200 (e.g., of the pad 215).

The circuit 200 may include a transmission component 205 and a reception component 210, which may each be coupled with a pad 215 via a line 220. The transmission component 205 may be configured to drive signaling along the line 220 to the pad 215. For example, the transmission component 205 may transmit signaling indicative of data (e.g., data read from the memory system 110) to the pad 215, and the pad 215 may be configured to output the data to the host system 105 (e.g., via a data line). The reception component 210 may be configured to receive signaling from the pad 215 via the line 220. For example, the pad 215 may receive data (e.g., data to be written to the memory system 110) from the host system 105 (e.g., via the data line), and the reception component 210 may receive signaling indicative of the data from the pad 215. That is, the pad 215 may be configured to receive and transmit signaling between the memory system 110 and the host system 105.

The transmission component 205 may include output drivers 225 configured to drive the signaling along the line 220. For example, FIG. 2 illustrates the transmission component 205 including two output drivers 225-a and 225-b, however the transmission component 205 may include a different quantity of output drivers 225. In some cases, the output drivers 225 may each include a transistor 230, which may be a p-channel metal-oxide semiconductor (PMOS) transistor or an n-channel metal-oxide semiconductor (NMOS) transistor. For example, the output driver 225-a may include a PMOS transistor 230-a coupled with a voltage source 226, and the output driver 225-b may include an NMOS transistor 230-b coupled with a ground terminal 227. In some cases, the output drivers 225 may include resistors 235, such that the output driver 225-a may include a resistor 235-a and the output driver 225-b may include a resistor 235-b.

The reception component 210 may include a receiver 240 that includes one or more transistors 245. For example, the receiver 240 may include a PMOS transistor 245-a coupled with a voltage source 228, and an NMOS transistor 245-b coupled the ground terminal 227. In some cases, to protect input gates of the receiver 240, the receiver 240 may be implemented behind a protection circuit (e.g., the current stabilization component 250-a) including a series resistor (e.g., the resistor 251) and diode elements (e.g., the resistive diodes 255) at the receiver input. For example, the receiver 240 may be coupled with a current stabilization component 250-a. The current stabilization component 250-a may include resistive diodes 255 and a resistor 251 configured to mitigate (e.g., prevent) current spiking from adversely affecting the receiver 240. For example, the current stabilization component 250-a may include a resistive diode 255-a (e.g., coupled with a voltage source) and a resistive diode 255-b (e.g., coupled with a ground terminal) coupled with the line 220 and configured to prevent a peak current from affecting (e.g., damaging) the receiver 240.

The circuit 200 may include another current stabilization component 250-b. For example, the current stabilization component 250-b may be coupled with the transmission component 205. In some examples, the current stabilization component 250-b may be coupled with the line 220 such that the current stabilization component 250-b may be coupled with the transmission component 205 and the reception component 210. The current stabilization component 250-b may include resistive diodes 255 configured to prevent current spiking from affecting the circuit 200. For example, the current stabilization component 250-b may include a resistive diode 255-c (e.g., coupled with a voltage source) and a resistive diode 255-d (e.g., coupled with a ground terminal) coupled with the line 220 and configured to prevent a peak current from affecting (e.g., damaging) the transmission component 205.

In some cases, the circuit 200 may be configured to selectively couple the transmission component 205 and the reception component 210 with the pad 215. For example, the circuit 200 may be configured to couple the transmission component 205 with the pad 215 during a transmission operation (e.g., transmitting data read from the memory system 110 to the host system 105). In some such examples, coupling the transmission component 205 with the pad 215 may result in the reception component 210 being decoupled from the pad 215 during the transmission operation. Likewise, the circuit 200 may be configured to couple the reception component 210 with the pad 215 during a reception operation (e.g., receiving write data from the host system 105). In some such examples, coupling the reception component 210 with the pad 215 may result in the transmission component 205 being decoupled from the pad 215 during the reception operation. In some cases, selectively coupling the transmission component 205 or the reception component 210 with the pad 215 may include disabling one or more voltages (e.g., source voltages) from being applied to the transmission component 205 or the reception component 210. For example, to terminate a channel connection with the reception component 210, one or more voltages applied to the reception component 210 may be disabled. Likewise, to terminate a channel connection with the transmission component 205, one or more voltages applied to the transmission component 205 may be disabled. In some implementations, a quantity of voltages disabled may be associated with a desired impedance of the transmission component 205 or the reception component 210.

The circuit 200 may include a series inductor 260 configured to reduce parasitic capacitance of the circuit 200. For example, the current stabilization component 250-a and the current stabilization component 250-b may produce parasitic capacitance by leaking charge onto the line 220. However, the series inductor 260 may reduce the parasitic capacitance that the pad 215 may otherwise have. In some cases, implementing the series inductor 260 coupled with the transmission component 205, the reception component 210, the current stabilization component 250-b, and the pad 215 via the line 220 may enable relatively increased data throughput by the pad 215, which may support improved throughput between the memory system 110 and the host system 105.

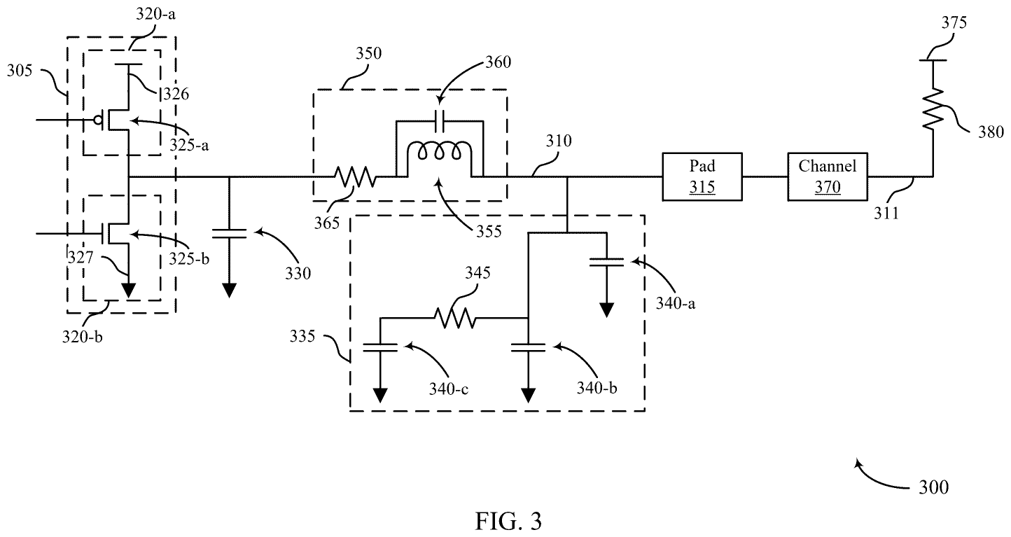

FIG. 3 shows an example of a circuit 300 that supports an output driver with compact inductive peaking in accordance with examples as disclosed herein. The circuit 300 may be implemented within a system, which may be an example of a system 100, as described with reference to FIG. 1. For example, the circuit 200 may be implemented within the memory system 110 and facilitate communications with the host system 105. In some examples, the circuit 200 may be implemented at a memory device 145 (e.g., within a local controller 150 of the memory device 145) or at a memory system controller 140. Further, the circuit 300 may implement aspects or operations of the circuit 200, as described with reference to FIG. 2. For example, the circuit 300 may illustrate a transmission side of the circuit 200, such that the circuit 300 may not illustrate the reception component 210. Although some circuit elements of the circuit 300 may be illustrated according to an order along (e.g., within) the circuit, the elements of the circuit 300 may be implemented in various other orders not shown. The circuit 300 may implement a series inductor which may be configured to reduce a parasitic capacitance of the circuit 300 (e.g., of the pad 315).

The circuit 300 may include a transmission component 305, which may be an example of a transmission component 205, as described with reference to FIG. 2. The transmission component 305 may be configured to drive signaling along a line 310 to the pad 315. For example, the transmission component 305 may transmit signaling indicative of data (e.g., data read from the memory system 110) to the pad 315, and the pad 315 may be configured to output the data to the host system 105 via a data line 311. The transmission component 305 may include output drivers 320, which may be examples of output drivers 225, and may be configured to drive the signaling along the line 310. For example, FIG. 3 illustrates the transmission component 305 including two output drivers 320-a and 320-b, however the transmission component 305 may include a different quantity of output drivers 320. In some cases, the output drivers 320 may be coupled together in parallel, and may be collectively coupled in series with the line 310. The line 310 may be a signal path extending between various elements of the circuit 300. In some cases, the line 310 may be interrupted by various elements of the circuit 300, such that the line 310 may refer to a signal path extending before and after an element of the circuit 300. For example, the line 310 may be connected with an input terminal of a series inductor 350 of the circuit 300 and the line 310 may be connected with an output terminal of the series inductor 350.

In some cases, the output drivers 320 may each include a transistor 325, which may be a PMOS transistor or an NMOS transistor. For example, the output driver 320-a may include a PMOS transistor 325-a, and the output driver 320-b may include an NMOS transistor 325-b. The PMOS transistor 325-a may be coupled with a voltage source 326, which may be an example of a voltage source VSS configured to apply a voltage (e.g., a positive voltage) to the source of the PMOS transistor 325-a. The NMOS transistor 325-b may be coupled with a ground terminal or a voltage source 327, which may be an example of a voltage source VDD configured to apply a voltage (e.g., a zero voltage, a negative voltage) to the drain of the NMOS transistor 325-b. In some cases, each transistor 325 may receive a threshold voltage at a gate of the respective transistor 325. In some such cases, the threshold voltages of the gates of the transistors 325 may be associated with signaling data along the line 310, such that when the threshold voltages are satisfied, the transistors may transmit the signaling along the line 310. In some examples, the output drivers 320 may include resistors coupled with the transistors 325.

The circuit 300 may include a drain capacitor 330 coupled with the transmission component 305. For example, the drain capacitor 330 may be coupled with the output drivers 320 in series via the line 310. The drain capacitor 330 may be associated with storing charge associated with the output drivers 320. That is, the output drivers 320 may leak charge onto the line 310, and the drain capacitor 330 may store the charge. In another example, during a transmission operation, the output drivers 320 may transmit signaling along the line 310, which may include transferring charge along the line 310. However, the charge transferred along the line 310 may be relatively high, thus the drain capacitor 330 may store the excess charge on the line 310. In some cases, the drain capacitor 330 may also be coupled with a ground terminal. In some cases, the drain capacitor 330 may be associated with producing a parasitic capacitance on the line 310 based on charge stored at the drain capacitor 330 leaking onto the line 310.

The circuit 300 may include a current stabilization component 335, which may be an example of a current stabilization component 250-b. The current stabilization component 335 may be coupled with the line 310 and may be configured to prevent current spiking on the line 310. That is, the current stabilization component 335 may prevent a current on the line 310 from exceeding a threshold. In some cases, implementing the current stabilization component 335 may prevent a peak current from affecting (e.g., damaging) the transmission component 305 or the pad 315. The current stabilization component 335 may include a quantity of capacitors 340 and a quantity of resistors 345. For example, the current stabilization component 335 may include capacitors 340-a, 340-b, and 340-c, as well as a resistor 345.

In some implementations, the capacitors 340-b and 340-c may be coupled in parallel with the resistor 345, which may be collectively coupled in parallel with the capacitor 340-a. In some such implementations, the capacitors 340 may each also be coupled with a respective ground terminal. In some examples, the current stabilization component 335 may implement resistive diodes in addition to, or instead of, the quantity of capacitors 340 and the quantity of resistors 345. In some cases, the current stabilization component 335 may be associated with producing a parasitic capacitance on the line 310 based on leaking charge stored at the capacitors 340. For example, the capacitors 340 may each be associated with storing charge associated with preventing current spiking, however, the capacitors may leak the stored charge onto the line 310. In some cases, the current on the line 310 may be within a range (e.g., above a first value and below a second value) based on the current stabilization component 335.

The circuit 300 may include a series inductor 350, which may be an example of a series inductor 260. The series inductor 350 may be coupled with the line 310 and may be configured to reduce parasitic capacitance of the circuit 300. That is, the transmission component 305, the drain capacitor 330, the current stabilization component 335, and the series inductor 350 may be coupled with the line 310 in series, and the series inductor 350 may reduce parasitic capacitance on the line 310 and at the pad 315. For example, the drain capacitor 330 and the current stabilization component 335 may be associated with a capacitance. However, the series inductor 350 may reduce the parasitic capacitance of the pad 315 due to its inductance and resistance. Additionally or alternatively, intrinsic resistance (e.g., the resistance of the routing) of the series inductor 350 may be tailored (e.g., adjusted, set) to optimize or otherwise calibrate the impedance of the output drivers 320 for a specific level of linearity.

In some examples, the capacitance of the pad 315 may be based on the series inductor 350 reducing the parasitic charge on the line 310. For example, the capacitance of the pad 315 when communicating data (e.g., outputting data, receiving data) may be less than a threshold value based on the series inductor 350. In some such examples, the threshold value may be indicative of a capacitance at which the circuit 300 may communicate data at a desired throughput, bandwidth, or latency.

In some cases, the series inductor 350 may include a single coil inductor 355 coupled with the line 310. In some such cases, the series inductor 350 may include a capacitor 360 coupled with the line 310 and coupled with the single coil inductor 355 in parallel. Further, the series inductor 350 may include a resistor 365 coupled with the line 310 and coupled with the single coil inductor 355 and the capacitor 360 in series via the line 310. In some cases, implementing the resistor 365 in series with the single coil inductor 355 may allow for resistors associated with the output drivers 320 to not be implemented in the circuit 300. For example, the output drivers 320 may not include resistors 235 (e.g., the resistor 235-a and the resistor 235-b as described with reference to FIG. 2) based on the serial implementation of the resistor 365 in the series inductor 350. In some such cases, refraining from implementing the resistors in series with the output drivers 320 may support improved scaling of the transmission component 305 by reducing the size allocated for the resistors of the output drivers 320. The series inductor 350 may be associated with a resistance (e.g., via the resistor 365) and an inductance (e.g., via the single coil inductor 355), such that a capacitance of the pad 315 may be based on the resistance and the inductance of the series inductor 350. FIG. 3 illustrates the series inductor 350 with the single coil inductor 355, the capacitor 360, and the resistor 365, however it should be understood that the series inductor 350 illustrated in FIG. 3 is one example of multiple variations of the series inductor 350. For example, the series inductor 350 may implement other circuit elements or other arrangements of the circuit elements to produce the resistance and the inductance on the line 310.

The circuit 300 may include a channel 370 coupled with the pad 315. That is, the pad 315 may be configured to communicate with the host system 105 via the channel 370. For example, the pad 315 may receive data and/or signaling at the memory system 110 from the host system 105 via the data line 311 and the channel 370. Likewise, the pad 315 may transmit data and/or signaling from the memory system 110 to the host system 105 via the data line 311 coupled with the channel 370. Thus, the channel 370 may extend between the memory system 110 and the host system 105, and may be configured to carry data and/or signaling between the memory system 110 and the host system 105. In some cases, the channel 370 may include a package substrate, a bond wire, or other components of the associated memory system. Additionally, or alternatively, the channel 370 may be coupled with a terminal 375 of the host system 105. In some such cases, the channel 370 may be coupled with a resistor 380 and the terminal 375 in series. In some cases, an impedance of the channel 370 may be based on a resistance associated with the resistor 380 and the terminal 375 based on the arrangement of the circuit 300.

In some cases, implementing the series inductor 350 may reduce the parasitic capacitance of the circuit 300, such that the circuit 300 may reliably communicate relatively large quantities of data with relatively low latency. For example, the capacitance of the pad 315 may support communicating the relatively large quantities of data with relatively low latency based on the resistance and the inductance of the series inductor 350. Additionally or alternatively, the series inductor 350 may be implemented in other devices, such as devices implementing pulse amplitude modulation (PAM) (e.g., PAM-3, PAM4) having a common inductor output. In other examples, the series inductor 350 may be implemented in devices having other forms of transmitter equalization that can be enabled simultaneously, such as AC coupled pre-emphasis drivers. In some such cases, implementing the series inductor 350 within the circuit 300 may be associated with relatively increased throughput between the memory system 110 and the host system 105.

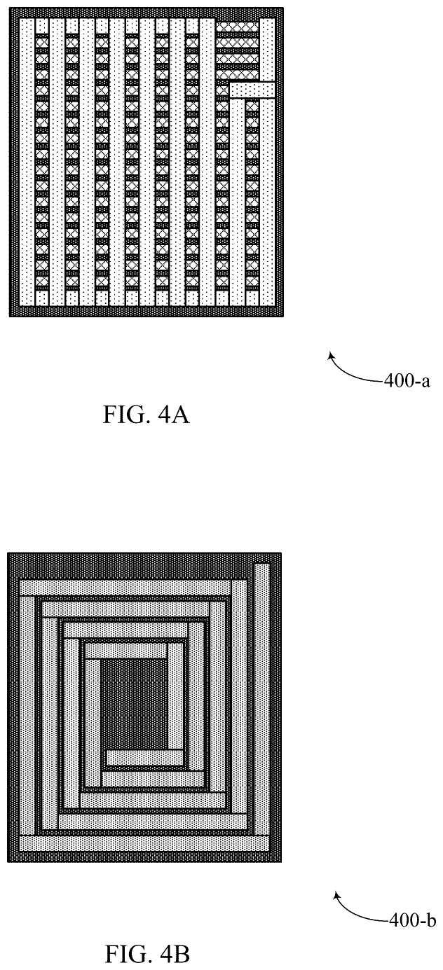

FIGS. 4A and 4B show examples of memory architectures 400 that support an output driver with compact inductive peaking in accordance with examples as disclosed herein. The memory architectures 400 may be implemented within a system, which may be an example of a system 100, as described with reference to FIG. 1. For example, the memory architectures 400 may be implemented within the memory system 110 in a memory array 155. The memory architectures 400 may show examples of different levels of a memory architecture in which an I/O circuit may be implemented. For example, each memory architecture 400 may implement the circuit 200 or the circuit 300, as described with reference to FIGS. 2 and 3, respectively.

FIG. 4A illustrates the memory architecture 400-a from a cross-sectional view relative to a substrate. That is, the memory architecture 400-a illustrates a level of a memory architecture, where the level is a top level. For example, the memory architecture 400-a may be associated with top layer metals or redistribution layer metals (e.g., an inline redistribution layer (iRDL)). The memory architecture 400-a may include one or more elements of the I/O circuit. That is, the memory architecture 400-a illustrates one or more elements of the I/O circuit being implemented within the top layer metals or the redistribution layer metals. For example, the memory architecture 400-a may illustrate a component being implemented using the top layer metals or the redistribution layer metals. In some examples, implementing components within the top layer metals or the redistribution layer metals may be associated with relatively large space consumption of the memory architecture 400-a. That is, components fabricated using the iRDL may be associated with a relatively larger pitch, which may occupy more space of the memory architecture 400-a.

FIG. 4B illustrates the memory architecture 400-b from a cross-sectional view relative to a substrate. That is, the memory architecture 400-b illustrates a level of a memory architecture, where the level is a lower level (e.g., a level below the iRDL, a relatively low metal level). For example, the memory architecture 400-b may be associated with low layer (e.g., low level) metals. The memory architecture 400-b may include one or more elements of the I/O circuit. That is, the memory architecture 400-b illustrates one or more elements of the I/O circuit being implemented within the low layer metals (e.g., M5 layers, M6 layers). For example, the memory architecture 400-b may illustrate a series inductor, which may be an example of a series inductor 260 or a series inductor 350, being implemented using the low layer metals. In some implementations, the series inductor may be a lossy inductor (e.g., an inductor exhibiting electrical resistance and dissipating energy in the form of heat). In some examples, implementing the series inductor within the low layer metals may be associated with relatively low space consumption of the memory architecture 400-b relative to fabricating components (e.g., a series inductor) in relatively higher-layer metals (e.g., the iRDL). That is, by fabricating the series inductor in a lower-layer metal, the series inductor may have a relatively smaller pitch than if fabricated in the iRDL, and thus may occupy a smaller space of the memory architecture 400-b (e.g., compared to the memory architecture 400-a).

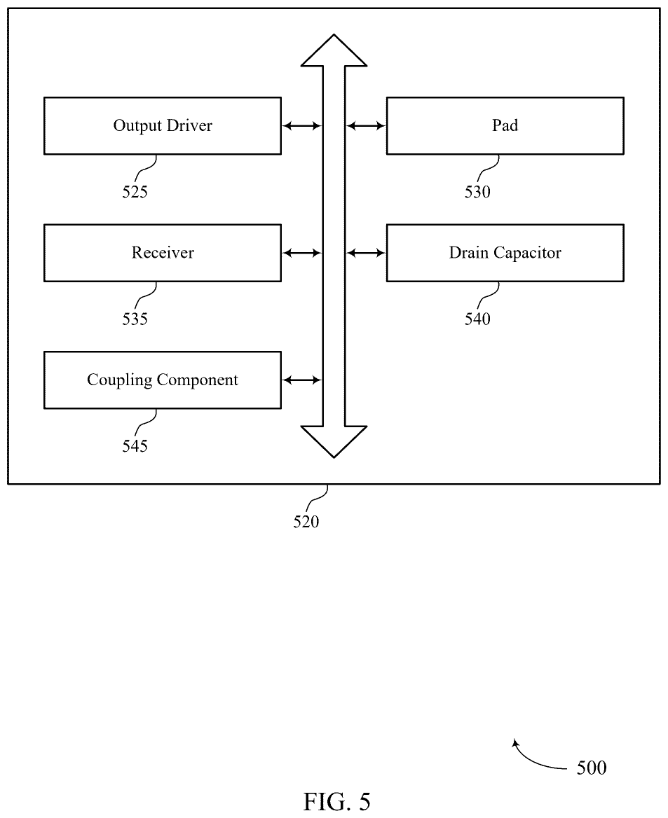

FIG. 5 shows a block diagram 500 of a circuit 520 that supports an output driver with compact inductive peaking in accordance with examples as disclosed herein. The circuit 520 may be an example of aspects of a circuit as described with reference to FIGS. 1 through 4. The circuit 520, or various components thereof, may be an example of means for performing various aspects of output driver with compact inductive peaking as described herein. For example, the circuit 520 may include an output driver 525, a pad 530, a receiver 535, a drain capacitor 540, a coupling component 545, or any combination thereof. Each of these components, or components of subcomponents thereof (e.g., one or more processors, one or more memories), may communicate, directly or indirectly, with one another (e.g., via one or more buses).

The output driver 525 may be configured as or otherwise support a means for driving a line coupled with a pad to a first value, where a current associated with the line is above a first value and below a second value based at least in part on a one or more capacitors and one or more resistors coupled with the pad. The pad 530 may be configured as or otherwise support a means for outputting data via a data line coupled with the pad based at least in part on driving the line to the first value, where a capacitance associated with the pad when outputting the data is less than a threshold value based at least in part on a resistance and an inductance of a series inductor coupled with the pad.

In some examples, the receiver 535 may be configured as or otherwise support a means for receiving second data via the pad, where the capacitance associated with the pad when receiving data is based at least in part on the resistance and the inductance of the series inductor.

In some examples, the coupling component 545 may be configured as or otherwise support a means for coupling an output driver to the pad when driving the data line to the first value.

In some examples, a current of the line is between a first current value and a second current value when the line is driven to the first value.

In some examples, the drain capacitor 540 may be coupled with an output driver and the series inductor and configured as or otherwise support a means for storing a charge based at least in part on driving the line to the first value.

In some examples, the described functionality of the circuit 520, or various components thereof, may be supported by or may refer to at least a portion of at least one processor, where such at least one processor may include one or more processing elements (e.g., a controller, a microprocessor, a microcontroller, a digital signal processor, a state machine, discrete gate logic, discrete transistor logic, discrete hardware components, or any combination of one or more of such elements). In some examples, the described functionality of the circuit 520, or various components thereof, may be implemented at least in part by instructions (e.g., stored in memory, non-transitory computer-readable medium) executable by such at least one processor.

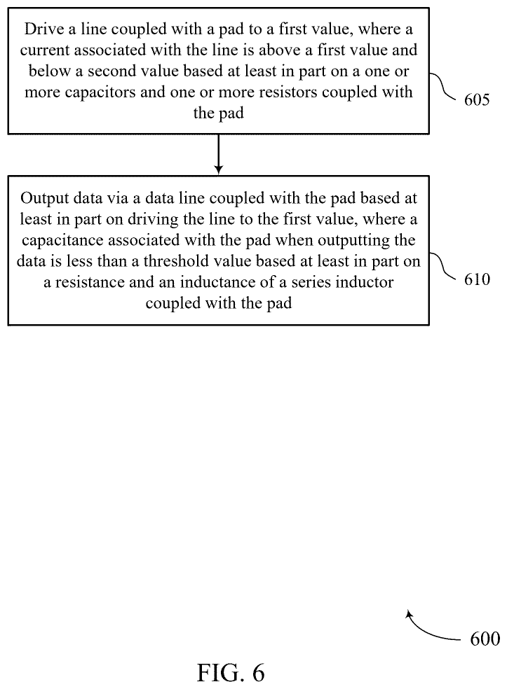

FIG. 6 shows a flowchart illustrating a method 600 that supports an output driver with compact inductive peaking in accordance with examples as disclosed herein. The operations of method 600 may be implemented by a circuit or its components as described herein. For example, the operations of method 600 may be performed by a circuit as described with reference to FIGS. 1 through 5. In some examples, a circuit may execute a set of instructions to control the functional elements of the device to perform the described functions. Additionally, or alternatively, the circuit may perform aspects of the described functions using special-purpose hardware.

At 605, the method may include driving a line coupled with a pad to a first value, where a current associated with the line is above a first value and below a second value based at least in part on a one or more capacitors and one or more resistors coupled with the pad. In some examples, aspects of the operations of 605 may be performed by an output driver 525 as described with reference to FIG. 5.

At 610, the method may include outputting data via a data line coupled with the pad based at least in part on driving the line to the first value, where a capacitance associated with the pad when outputting the data is less than a threshold value based at least in part on a resistance and an inductance of a series inductor coupled with the pad. In some examples, aspects of the operations of 610 may be performed by a pad 530 as described with reference to FIG. 5.

In some examples, an apparatus as described herein may perform a method or methods, such as the method 600. The apparatus may include features, circuitry, logic, means, or instructions (e.g., a non-transitory computer-readable medium storing instructions executable by a processor), or any combination thereof for performing the following aspects of the present disclosure:

Aspect 1: A method, apparatus, or non-transitory computer-readable medium including operations, features, circuitry, logic, means, or instructions, or any combination thereof for driving a line coupled with a pad to a first value, where a current associated with the line is above a first value and below a second value based at least in part on a one or more capacitors and one or more resistors coupled with the pad and outputting data via a data line coupled with the pad based at least in part on driving the line to the first value, where a capacitance associated with the pad when outputting the data is less than a threshold value based at least in part on a resistance and an inductance of a series inductor coupled with the pad.

Aspect 2: The method, apparatus, or non-transitory computer-readable medium of aspect 1, further including operations, features, circuitry, logic, means, or instructions, or any combination thereof for receiving, by a receiver, second data via the pad, where the capacitance associated with the pad when receiving data is based at least in part on the resistance and the inductance of the series inductor.

Aspect 3: The method, apparatus, or non-transitory computer-readable medium of aspect 2, further including operations, features, circuitry, logic, means, or instructions, or any combination thereof for coupling an output driver to the pad when driving the data line to the first value.

Aspect 4: The method, apparatus, or non-transitory computer-readable medium of any of aspects 1 through 3, where a current of the line is between a first current value and a second current value when the line is driven to the first value.

Aspect 5: The method, apparatus, or non-transitory computer-readable medium of any of aspects 1 through 4, further including operations, features, circuitry, logic, means, or instructions, or any combination thereof for storing, by a drain capacitor coupled with an output driver and the series inductor, a charge based at least in part on driving the line to the first value.

It should be noted that the aspects described herein describe possible implementations, and that the operations and the steps may be rearranged or otherwise modified and that other implementations are possible. Further, portions from two or more of the methods may be combined.

An apparatus is described. The following provides an overview of aspects of the apparatus as described herein:

Aspect 6: An I/O circuit, including: an output driver; a series inductor coupled with the output driver and including a resistance and an inductance; and a pad coupled with the series inductor and a data line, where the pad is configured to output data to the data line based at least in part on the output driver generating a signal, and where a capacitance associated with the pad when outputting data to the data line is less than a threshold value based at least in part on the resistance and the inductance of the series inductor.

Aspect 7: The I/O circuit of aspect 6, further including: a receiver coupled with the series inductor and configured to receive data, where the capacitance associated with the pad when receiving data via the data line is based at least in part on the resistance and the inductance of the series inductor.

Aspect 8: The I/O circuit of aspect 7, where the output driver and the receiver are configured to selectively couple with the pad.

Aspect 9: The I/O circuit of any of aspects 6 through 8, further including: a line coupled with the series inductor and the pad; and a current stabilization component coupled with the line, where a current of the line is based at least in part on the current stabilization component.

Aspect 10: The I/O circuit of aspect 9, where the current of the line includes a peak current of the line.

Aspect 11: The I/O circuit of any of aspects 6 through 10, where the series inductor is formed in a metal layer below an inline redistribution layer (iRDL).

Aspect 12: The I/O circuit of any of aspects 6 through 11, further including: a second output driver coupled with the series inductor, where the output driver and the second output driver are coupled.

Aspect 13: The I/O circuit of aspect 12, further including: a drain capacitor coupled with the output driver, the second output driver, and the series inductor.

Aspect 14: The I/O circuit of aspect 13, where the capacitance associated with the pad is based at least in part on the drain capacitor being coupled with the output driver, the second output driver, and the series inductor.

Aspect 15: The I/O circuit of any of aspects 6 through 14, where the output driver is configured to drive the data to the pad.

Aspect 16: The I/O circuit of any of aspects 6 through 15, where the series inductor includes: an inductor, a resistor, and a capacitor coupled with the data line.

Aspect 17: The I/O circuit of any of aspects 6 through 16, where the output driver, the series inductor, and the pad are coupled with the data line.

An apparatus is described. The following provides an overview of aspects of the apparatus as described herein:

Aspect 18: A memory device, including: one or more memory arrays; and processing circuitry coupled with the one or more memory arrays, where the processing circuitry is configured to cause the memory device to: drive a line coupled with a pad to a first value, where a current associated with the line is above a first value and below a second value based at least in part on a one or more capacitors and one or more resistors coupled with the pad; and output data via a data line coupled with the pad based at least in part on driving the line to the first value, where a capacitance associated with the pad when outputting the data is less than a threshold value based at least in part on a resistance and an inductance of a series inductor coupled with the pad.

Aspect 19: The memory device of aspect 18, where the processing circuitry is configured to cause the memory device to: receive, by a receiver, second data via the pad, where the capacitance associated with the pad when receiving data is based at least in part on the resistance and the inductance of the series inductor.

Aspect 20: The memory device of any of aspects 18 through 19, where the processing circuitry is configured to cause the memory device to: couple an output driver to the pad when driving the data line to the first value.

Information and signals described herein may be represented using any of a variety of different technologies and techniques. For example, data, instructions, commands, information, signals, bits, or symbols of signaling that may be referenced throughout the above description may be represented by voltages, currents, electromagnetic waves, magnetic fields or particles, optical fields or particles, or any combination thereof. Some drawings may illustrate signals as a single signal; however, the signal may represent a bus of signals, where the bus may have a variety of bit widths.

The terms “electronic communication,” “conductive contact,” “connected,” and “coupled” may refer to a relationship between components that supports the flow of signals between the components. Components are considered in electronic communication with (e.g., in conductive contact with, connected with, coupled with) one another if there is any electrical path (e.g., conductive path) between the components that can, at any time, support the flow of signals (e.g., charge, current, voltage) between the components. A conductive path between components that are in electronic communication with each other (e.g., in conductive contact with, connected with, coupled with) may be an open circuit or a closed circuit based on the operation of the device that includes the connected components. A conductive path between connected components may be a direct conductive path between the components or may be an indirect conductive path that includes intermediate components, such as switches, transistors, or other components. In some examples, the flow of signals between the connected components may be interrupted for a time, for example, using one or more intermediate components such as switches or transistors.

The term “isolated” may refer to a relationship between components in which signals are not presently capable of flowing between the components. Components are isolated from each other if there is an open circuit between them. For example, two components separated by a switch that is positioned between the components are isolated from each other when the switch is open. When a component isolates two components, the component may initiate a change that prevents signals from flowing between the other components using a conductive path that previously permitted signals to flow.

The term “coupling” (e.g., “electrically coupling”) may refer to condition of moving from an open-circuit relationship between components in which signals are not presently capable of being communicated between the components (e.g., over a conductive path) to a closed-circuit relationship between components in which signals are capable of being communicated between components (e.g., over the conductive path). When a component, such as a controller, couples other components together, the component may initiate a change that allows signals to flow between the other components over a conductive path that previously did not permit signals to flow.

The terms “layer” and “level” may refer to an organization (e.g., a stratum, a sheet) of a geometrical structure (e.g., relative to a substrate). Each layer or level may have three dimensions (e.g., height, width, and depth) and may cover at least a portion of a surface. For example, a layer or level may be a three dimensional structure where two dimensions are greater than a third, e.g., a thin-film. Layers or levels may include different elements, components, or materials. In some examples, one layer or level may be composed of two or more sublayers or sublevels.

The devices discussed herein, including a memory array, may be formed on a semiconductor substrate, such as silicon, germanium, silicon-germanium alloy, gallium arsenide, gallium nitride, etc. In some examples, the substrate is a semiconductor wafer. In some other examples, the substrate may be a silicon-on-insulator (SOI) substrate, such as silicon-on-glass (SOG) or silicon-on-sapphire (SOS), or epitaxial layers of semiconductor materials on another substrate. The conductivity of the substrate, or sub-regions of the substrate, may be controlled through doping using various chemical species including, but not limited to, phosphorous, boron, or arsenic.

A switching component (e.g., a transistor) discussed herein may be a field-effect transistor (FET), and may include a source (e.g., a source terminal), a drain (e.g., a drain terminal), a channel between the source and drain, and a gate (e.g., a gate terminal). A conductivity of the channel may be controlled (e.g., modulated) by applying a voltage to the gate which, in some examples, may result in the channel becoming conductive. A switching component may be an example of an n-type FET or a p-type FET.

The description set forth herein, in connection with the appended drawings, describes example configurations and does not represent all the examples that may be implemented or that are within the scope of the claims. The detailed description includes specific details to provide an understanding of the described techniques. These techniques, however, may be practiced without these specific details. In some instances, well-known structures and devices are shown in block diagram form to avoid obscuring the concepts of the described examples.

In the appended figures, similar components or features may have the same reference label. Similar components may be distinguished by following the reference label by one or more dashes and additional labeling that distinguishes among the similar components. If just the first reference label is used in the specification, the description is applicable to any one of the similar components having the same first reference label irrespective of the additional reference labels.

The functions described herein may be implemented in hardware, software executed by a processing system (e.g., one or more processors, one or more controllers, control circuitry processing circuitry, logic circuitry), firmware, or any combination thereof. If implemented in software executed by a processing system, the functions may be stored on or transmitted over as one or more instructions (e.g., code) on a computer-readable medium. Due to the nature of software, functions described herein can be implemented using software executed by a processing system, hardware, firmware, hardwiring, or combinations of any of these. Features implementing functions may be physically located at various positions, including being distributed such that portions of functions are implemented at different physical locations.

Illustrative blocks and modules described herein may be implemented or performed with one or more processors, such as a DSP, an ASIC, an FPGA, discrete gate logic, discrete transistor logic, discrete hardware components, other programmable logic device, or any combination thereof designed to perform the functions described herein. A processor may be an example of a microprocessor, a controller, a microcontroller, a state machine, or other types of processors. A processor may also be implemented as at least one of one or more computing devices (e.g., a combination of a DSP and a microprocessor, multiple microprocessors, one or more microprocessors in conjunction with a DSP core, or any other such configuration).

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

As used herein, including in the claims, the article “a” before a noun is open-ended and understood to refer to “at least one” of those nouns or “one or more” of those nouns. Thus, the terms “a,” “at least one,” “one or more,” “at least one of one or more” may be interchangeable. For example, if a claim recites “a component” that performs one or more functions, each of the individual functions may be performed by a single component or by any combination of multiple components. Thus, the term “a component” having characteristics or performing functions may refer to “at least one of one or more components” having a particular characteristic or performing a particular function. Subsequent reference to a component introduced with the article “a” using the terms “the” or “said” may refer to any or all of the one or more components. For example, a component introduced with the article “a” may be understood to mean “one or more components,” and referring to “the component” subsequently in the claims may be understood to be equivalent to referring to “at least one of the one or more components.” Similarly, subsequent reference to a component introduced as “one or more components” using the terms “the” or “said” may refer to any or all of the one or more components. For example, referring to “the one or more components” subsequently in the claims may be understood to be equivalent to referring to “at least one of the one or more components.”

Computer-readable media includes both non-transitory computer storage media and communication media including any medium that facilitates transfer of a computer program from one place to another. A non-transitory storage medium may be any available medium, or combination of multiple media, which can be accessed by a computer. By way of example, and not limitation, non-transitory computer-readable media can comprise RAM, ROM, electrically erasable programmable read-only memory (EEPROM), optical disk storage, magnetic disk storage or other magnetic storage devices, or any other non-transitory medium or combination of media that can be used to carry or store desired program code means in the form of instructions or data structures and that can be accessed by a computer, or one or more processors.

The descriptions and drawings are provided to enable a person having ordinary skill in the art to make or use the disclosure. Various modifications to the disclosure will be apparent to the person having ordinary skill in the art, and the techniques disclosed herein may be applied to other variations without departing from the scope of the disclosure. Thus, the disclosure is not limited to the examples and designs described herein but is to be accorded the broadest scope consistent with the principles and novel features disclosed herein.

What is claimed is:

1. An input/output (I/O) circuit, comprising:
an output driver;
a series inductor coupled with the output driver and comprising a resistance and an inductance; and
a pad coupled with the series inductor and a data line, wherein the pad is configured to output data to the data line based at least in part on the output driver generating a signal, and wherein a capacitance associated with the pad when outputting data to the data line is less than a threshold value based at least in part on the resistance and the inductance of the series inductor.

2. The I/O circuit of claim 1, further comprising:
a receiver coupled with the series inductor and configured to receive data, wherein the capacitance associated with the pad when receiving data via the data line is based at least in part on the resistance and the inductance of the series inductor.

3. The I/O circuit of claim 2, wherein the output driver and the receiver are configured to selectively couple with the pad.

4. The I/O circuit of claim 1, further comprising:
a line coupled with the series inductor and the pad; and
a current stabilization component coupled with the line, wherein a current of the line is based at least in part on the current stabilization component.

5. The I/O circuit of claim 4, wherein the current of the line comprises a peak current of the line.

6. The I/O circuit of claim 1, wherein the series inductor is formed in a metal layer below an inline redistribution layer (iRDL).

7. The I/O circuit of claim 1, further comprising:
a second output driver coupled with the series inductor, wherein the output driver and the second output driver are coupled.

8. The I/O circuit of claim 7, further comprising:
a drain capacitor coupled with the output driver, the second output driver, and the series inductor.

9. The I/O circuit of claim 8, wherein the capacitance associated with the pad is based at least in part on the drain capacitor being coupled with the output driver, the second output driver, and the series inductor.

10. The I/O circuit of claim 1, wherein the output driver is configured to drive the data to the pad.

11. The I/O circuit of claim 1, wherein the series inductor comprises:
an inductor, a resistor, and a capacitor coupled with the data line.

12. The I/O circuit of claim 1, wherein the output driver, the series inductor, and the pad are coupled with the data line.

13. A method by an input/output (I/O) circuit, comprising:
driving a line coupled with a pad to a first value, wherein a current associated with the line is above a first value and below a second value based at least in part on a one or more capacitors and one or more resistors coupled with the pad; and
outputting data via a data line coupled with the pad based at least in part on driving the line to the first value, wherein a capacitance associated with the pad when outputting the data is less than a threshold value based at least in part on a resistance and an inductance of a series inductor coupled with the pad.

14. The method of claim 13, further comprising:
receiving, by a receiver, second data via the pad, wherein the capacitance associated with the pad when receiving data is based at least in part on the resistance and the inductance of the series inductor.

15. The method of claim 14, further comprising:
coupling an output driver to the pad when driving the data line to the first value.

16. The method of claim 13, wherein a current of the line is between a first current value and a second current value when the line is driven to the first value.

17. The method of claim 13, further comprising:
storing, by a drain capacitor coupled with an output driver and the series inductor, a charge based at least in part on driving the line to the first value.

18. A memory device, comprising:
one or more memory arrays; and
processing circuitry coupled with the one or more memory arrays, wherein the processing circuitry is configured to cause the memory device to:
drive a line coupled with a pad to a first value, wherein a current associated with the line is above a first value and below a second value based at least in part on a one or more capacitors and one or more resistors coupled with the pad; and
output data via a data line coupled with the pad based at least in part on driving the line to the first value, wherein a capacitance associated with the pad when outputting the data is less than a threshold value based at least in part on a resistance and an inductance of a series inductor coupled with the pad.

19. The memory device of claim 18, wherein the processing circuitry is configured to cause the memory device to:
receive, by a receiver, second data via the pad, wherein the capacitance associated with the pad when receiving data is based at least in part on the resistance and the inductance of the series inductor.

20. The memory device of claim 18, wherein the processing circuitry is configured to cause the memory device to:
couple an output driver to the pad when driving the data line to the first value.
